(19) United States
(12) Patent Application Publication
(10) Pub. No.: US 2016/0224397 A1
(43) Pub. Date: Aug. 4, 2016

(54) EXPLOITING LIMITED CONTEXT STREAMS

(71) Applicant: ADVANCED MICRO DEVICES, INC., Sunnyvale, CA (US)

(72) Inventors: Manish Arora, Sunnyvale (CA); Can Hankendi, Boxborough, MA (US); Syed Ali R. Jafri, Sunnyvale, CA (US); Andrew G. Kegel, Bellevue, WA (US)

(73) Assignee: ADVANCED MICRO DEVICES, INC., Sunnyvale, CA (US)

(21) Appl. No.: 14/610,662

(22) Filed: Jan. 30, 2015

(51) Int. Cl. G06F 9/52; G11C 7/10; G06F 12/02; G06F 9/50; G06F 9/46

(52) U.S. Cl. CPC G06F 9/528; G06F 9/5016; G06F 9/461; G06F 12/0246; G11C 7/1072; G06F 2212/7201

(57) ABSTRACT

In one form, a data processing system includes volatile and non-volatile memory, a central processing unit, and at least one peripheral device. The central processing unit executes a selected one of a plurality of software applications as directed by an operating system by transferring the selected software application from the non-volatile memory to the volatile memory and executing instructions associated with the selected software application from the volatile memory. The at least one peripheral device includes a real-time clock for defining execution contexts for the plurality of software applications. The data processing system further includes a usage pattern analyzer adapted to store history information associated with an execution context for each of the plurality of software applications, and to use the history information to direct the operating system to take at least one action based on the history information.

### FIELD

This disclosure relates generally to data processing systems, and more specifically to software control and execution for data processing systems.

### BACKGROUND

Computer systems include generally a central processing unit (CPU), a memory that stores software and data, and a set of input/output peripheral devices. The software includes both application programs and an operating system. The operating system establishes a human interface for the selection and execution of programs, and allows application programs to interface with computer hardware. The operating systems of mobile communication devices, commonly referred to as “smartphones”, “tablets”, and desktop computers are different in that the mobile operating system is especially adapted for the mobile environment. For example, mobile operating systems place special emphasis on saving power to preserve battery life while providing fast launch times for mobile applications. Thus there is an ongoing need to balance fast launching of mobile applications with the need conserve power in a way that improves the user's experience.

### BRIEF DESCRIPTION OF THE DRAWINGS

FIG. 1 illustrates in block diagram form a communication system having a mobile communication device.

FIG. 2 illustrates a flow diagram of a known method for starting and managing program execution in a mobile communication device.

FIG. 3 illustrates in block diagram form a data processing system for use in the mobile processing device of FIG. 1 according to some embodiments.

FIG. 4 illustrates in block diagram form a context-based execution controller for use in the data processing system of FIG. 3 according to some embodiments.

In the following description, the use of the same reference numerals in different drawings indicates similar or identical items. Unless otherwise noted, the word “coupled” and its associated verb forms include both direct connection and indirect connection by means known in the art, and unless otherwise noted any description of direct connection implies alternate embodiments using suitable forms of indirect connection as well.

### DETAILED DESCRIPTION OF ILLUSTRATIVE EMBODIMENTS

In one form, a data processing system includes a memory, a central processing unit, at least one peripheral device, and a context-based execution controller. The memory stores an operating system and a plurality of software applications. The central processing unit is coupled to the memory and executes a selected software application of the plurality of software applications as directed by the operating system. The at least one peripheral device includes a real-time clock for defining execution contexts for the plurality of software applications. The context-based execution controller is coupled to the memory and to the at least one peripheral device and takes at least one speculative action with respect to launching the selected software application in response to an execution context indicated by the at least one peripheral device.

In another form, a context-based execution controller for managing an application program execution environment for a mobile communication device or the like includes a usage pattern analyzer and a usage history table. The usage pattern analyzer is coupled to the usage history table and is responsive to a plurality of inputs including a real time signal and an application launch signal to form an execution context for each of a plurality of software applications based on the real time signal and the application launch signal. The usage pattern analyzer also stores the execution context in the usage history table, and the usage pattern analyzer further uses the real time signal to output an action request with respect to one of the plurality of software applications that is inactive.

In yet another form, a method includes receiving at least one execution context signal. An application launch signal is also received. History information is formed based on a plurality of inputs including the at least one execution context signal and the application launch signal. The history information is stored in a usage history table. The usage history table is accessed in response to the at least one execution context signal. An action request associated with a software application is provided based on the usage history table.

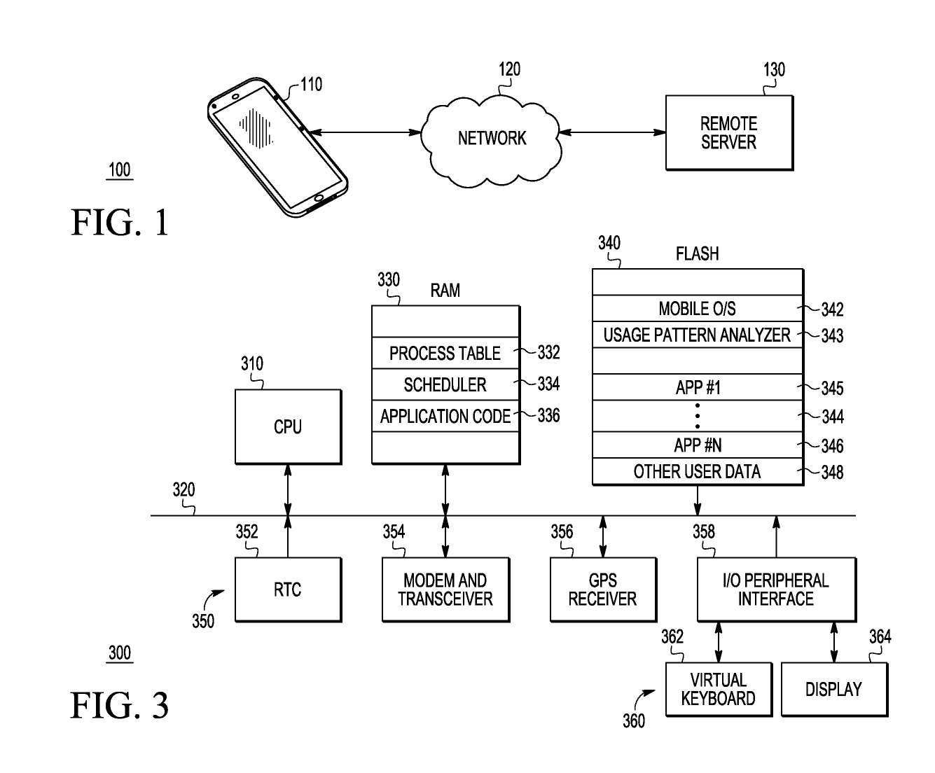

FIG. 1 illustrates in block diagram form a communication system 100 having a mobile communication device 110. In one example, mobile communication device 110 is a cellular telephone that communicates with other devices, including a remote server 130, over a network 120. Network 120 includes a cellular switch for connecting mobile communication device 110 to other telephones and a gateway for connection to the internet. Remote server 130 includes a computer system with mass memory storage for storing and delivering multimedia and other content.

Mobile communication device 110 is a hand-held device commonly referred to as a “smartphone” that not only provides voice communication over the cellular telephone network but also stores and executes a variety of application programs or “mobile apps” that offer a variety of useful functions such as EMAIL, calendar, internet browser, electronic book reader, games, and the like. To implement these mobile apps, mobile communication device 110 itself includes a data processing system complete with a central processing unit, memory for storing a mobile operating system and mobile apps, and input/output peripheral devices.

The execution environment of mobile communication device 110 creates the need to launch and execute mobile apps quickly while preserving battery life. The inventors have discovered that these environmental factors correlate with a user's propensity to launch certain mobile apps or to use certain data within the mobile apps. In order to enhance the user's experience, mobile communication device 110 operates to speculatively launch mobile apps and load data related to such mobile apps based on the execution context. As used herein, “execution context” includes a set of one or more environmental factors. For example, environmental factors can include such things as time of day or week, location, proximity to other mobile users, recent selection of other mobile apps, and the like.

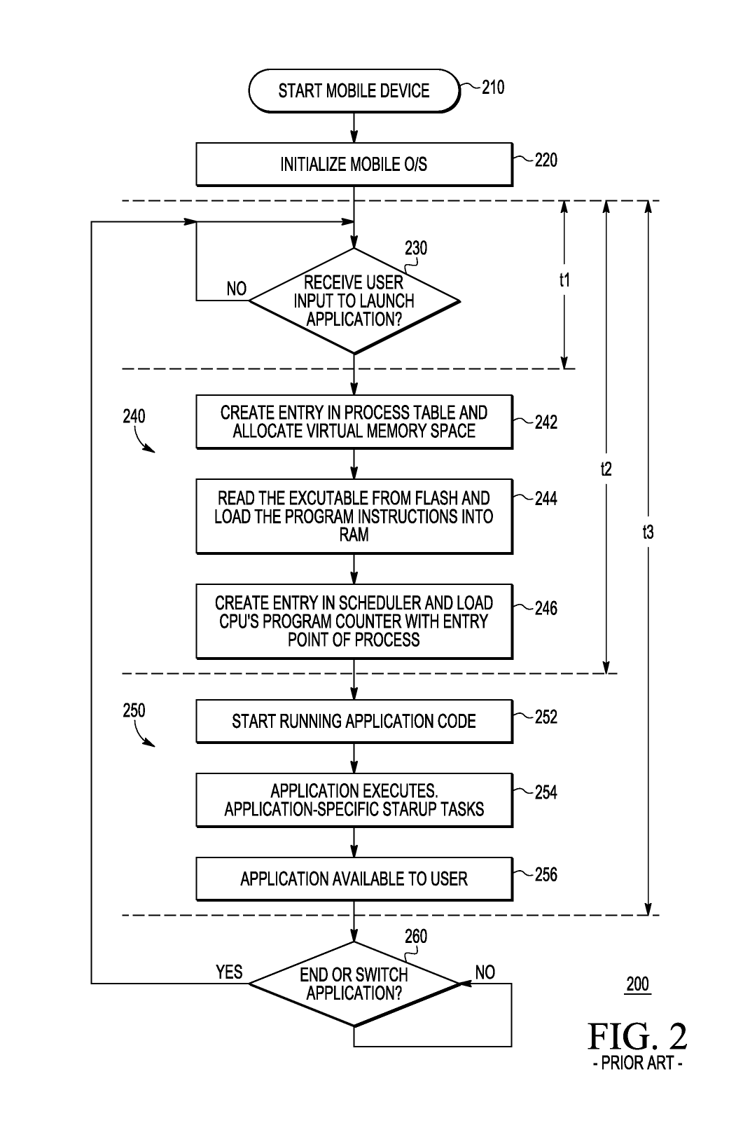

FIG. 2 illustrates a flow diagram 200 of a known method for starting and managing program execution in a mobile communication device. The method begins with an action box 210 in which a user starts the mobile device, for example by turning it on using a hard or soft switch. In response to being turned on, the mobile device initializes the mobile operating system in action box 220. Typically a mobile operating system starts in a significantly shorter period of time than a desktop operating system. The mobile communication device launches the mobile operating system by initializing peripherals, establishing communication with the cellular telephone network, initializing tables in memory, and the like.

When the mobile operating system has completed initialization, it creates a graphical user interface (GUI) to allow the user to interact with it. In most smartphones, the GUI provides icons corresponding to mobile apps underneath a touch screen such that the user can select an app by pressing a finger on an overlying position on the touch screen. The mobile operating system loops on a decision box 230 in which it waits for a user input to launch a mobile application.

When the user selects a mobile app to launch, the mobile operating system launches the application in a series of actions 240. In an action box 242, the mobile operating system creates an entry in a process table and allocates a virtual memory space. In an action box 244, the mobile operating system reads the executable instructions from a non-volatile (“FLASH”) memory and loads the instructions into a volatile memory that can be accessed significantly faster than the FLASH memory. In an action box 246, the mobile operating system creates an entry in a scheduler and loads a central processing unit's program counter with an entry point of a process associated with the mobile app. It should be apparent that actions 240 are merely exemplary and represent only the more significant steps in launching an application.

Flow continues to a series of actions 250 associated with running the mobile app. In an action box 252, the central processing unit starts running the application code by fetching the first instruction using the process table. Flow continues to action box 254, in which the mobile app executes application-specific startup tasks, including for example setting up tables in volatile memory, loading information about user preferences from non-volatile memory, setting up application-specific GUIs, and the like. Finally at action box 256, the application becomes available to the user.

Execution of the mobile app continues until the operating system detects an end to or switch of the application in decision box 260. For example, the user (or operating system) may close the application, or in the context of a multiple-application execution environment, switch the current application into the background and another application into the foreground.

It should be apparent from flow diagram 200 that there are many actions taken by the mobile operating system and the mobile app itself before the app is available to the user for its intended function. A reduction in the amount of time required before the application is available to the user when the user wants it would greatly enhance the user's subjective experience.

In particular, the inventors have discovered that by storing information over time about the context that existed for previous launches of a mobile app, the mobile operating system can partially hide the overhead from the user and make the application available to the user in anticipation of the user's desire to launch it. The inventors have observed that the context of the application establishes a likelihood of the user launching the application, especially in mobile communication devices. For example, the user may check EMAIL regularly at a certain time of day. The user may also launch a radio player application on entering a sports arena or stadium. Moreover the user may make certain predictable choices to the application. Thus both real time and geographical location may indicate the mobile app a user is likely to want or need, and enhance the user's experience by pre-launching the app predicted by the context.

FIG. 3 illustrates in block diagram form a data processing system 300 for use in the mobile processing device of FIG. 1 according to some embodiments. Data processing system 300 includes a central processing unit (CPU) 310 connected to a system bus 320. Also connected to system bus 320 is memory separated into a volatile random access memory (RAM) 330 and a non-volatile memory in the form of a flash erasable programmable read only memory (“FLASH memory”) 340, and a set of peripheral devices 350.

CPU 310 is a central processing unit that is adapted to execute stored program instructions while consuming only a small amount of power. The architecture of CPU 310 may vary from embodiment to embodiment. For example, CPU 310 can be a low power CPU designed and licensed by Advanced RISC Machines, Ltd.

RAM 330 includes memory that can be accessed by CPU 310 at high speed. A mobile operating system typically uses portions of RAM 330 to set up various data structures, such as a portion 332 for storing a process table, and a portion 334 for storing a scheduler. In addition, the operating system loads particular mobile apps, or portions thereof, into an application code portion 336 of RAM 330 so they can be executed at relatively high speed.

FLASH memory 340 is formed of inexpensive floating-gate memory, and includes several portions of interest including a portion 342 for storing the mobile operating system itself and another portion 344 for storing mobile apps including a portion 345 for storing a representative first app labeled “APP #1” and a portion 346 for storing a representative N^{th} app labeled “APP #N”, and a portion 348 for storing other user data.

Peripheral devices 350 include a real-time clock (RTC) 352, a modem and transceiver 354, a global positioning system (GPS) receiver 356, and an I/O peripheral interface 358. Real time clock 352 has an output for providing a signal indicative of real time that CPU 310 can correlate to time of the day, day of the week and year, etc. Modem and transceiver 354 provides various communication links, such as a cellular telephone system, a high-speed limited distance network known as “WiFi”, a short distance communication link known as near-field communication, and the like. GPS receiver 356 receives triangulation data from GPS satellites that allows the CPU to determine terrestrial location coordinates. I/O peripheral interface 358 provides a bridge to relatively low-speed peripherals, such as a virtual keyboard 362 from which CPU 310 receives user input and a display 364 which CPU 310 uses to output the GUI. As should be apparent, peripheral devices 350 are merely illustrative of the type of peripherals present in a typical mobile communication device.

In addition, FLASH memory 340 includes a portion 343 for storing a context based application controller. The context based application controller is connected to peripheral devices 350 over system bus 320 and is adapted to create and store history information associated with an execution context for each of the plurality of software applications. For example the context could be a combination of the time of day and a geographical location in which the mobile app is frequently launched. The context based application controller uses the history information to direct the mobile operating system to take at least one speculative action, such as pre-launching the mobile app or pre-loading certain data.

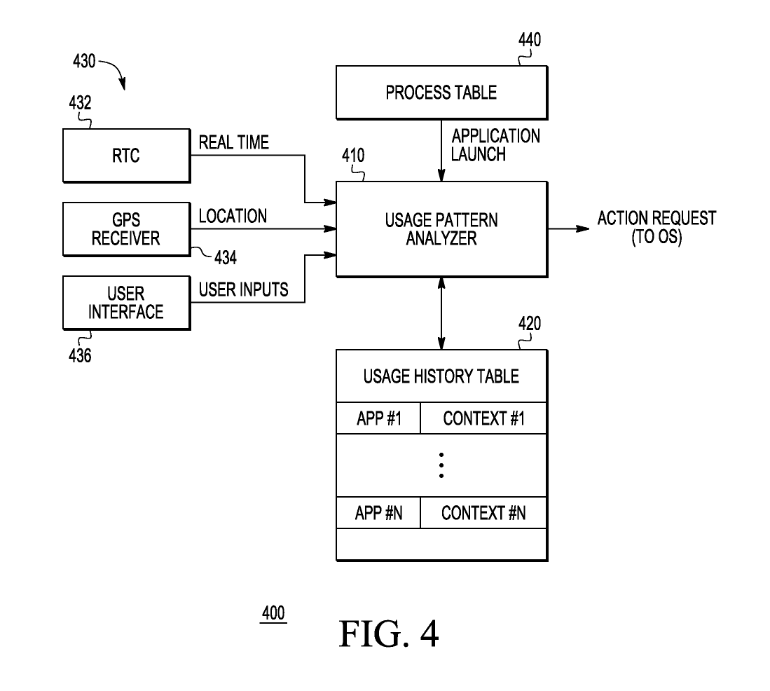

FIG. 4 illustrates in block diagram form a context-based execution controller 400 for use in data processing system 300 of FIG. 3 according to some embodiments. Context-based execution controller 400 includes a usage pattern analyzer 410 and a usage history table 420 interacting with a set of peripherals 430 and a process table 440. Usage pattern analyzer 410 has inputs for receiving signals indicating an execution context, an input for receiving an application launch signal, a bidirectional interface to usage history table 420, and an output for providing a signal labelled “ACTION REQUEST” to the operating system. Usage pattern analyzer 410 can be formed with various combinations of hardware and software. In some embodiments, usage pattern analyzer 410 is formed as a layer of the mobile operating system that interacts with other operation system layers using conventional methods. In other embodiments, usage pattern analyzer 401 itself is a mobile application capable of running concurrently with user applications. In still other applications, usage pattern analyzer is a hardware circuit.

Usage history table 420 is a table of entries created and maintained by usage pattern analyzer 410 in RAM 330 or FLASH memory 340. Each entry has an application indicator and context data corresponding to and associated with the software application. The application indicator indicates, directly or indirectly, a particular mobile application. In the example shown in FIG. 4, usage history table 420 has N entries including two exemplary entries. The first entry corresponds to a first mobile app labeled “APP #1” and has associated context data labeled “CONTEXT #1”. The N^{th} entry corresponds to an N^{th} mobile app labeled “APP #N” and has associated context data labeled “CONTEXT #N”. In some embodiments, the mobile operating system stores the usage history table in FLASH memory 340 upon shutdown, and retrieves it from FLASH memory 340 and stores in RAM 330 at operating system startup, and maintains it in RAM 330 during operation. In this way, the number of writes to FLASH memory 340 is kept low.

Peripherals 430 include a real time clock 432, a GPS receiver 434, and a user interface 436 corresponding to like elements in FIG. 3. Thus in the example shown in FIG. 4 peripherals 430 correspond to hardware blocks in data processing system 300. If context-based execution controller 400 is implemented as a layer of the operating system, then usage pattern analyzer 410 can receive context inputs by periodically polling the peripherals.

Process table 440 is located in a portion of RAM corresponding to portion 332 in FIG. 3 and is used by the mobile operating system to catalog active processes. It outputs the APPLICATION LAUNCH signal when the mobile operating system launches a new process. In this regard, the APPLICATION LAUNCH signal includes the application identifier and possibly other relevant information. When process table 440 outputs the APPLICATION LAUNCH signal, usage pattern analyzer 410 reads the current context and updates the corresponding entry in usage history table 420 so that, over time, usage pattern analyzer 410 “learns” the user's preferences. Moreover usage history table 440 has the capability to grow as the user adds new applications.

In operation, usage pattern analyzer 410 periodically receives or reads the context information and predicts applications that have a high probability of being launched by the user in the current context. Usage pattern analyzer 410 does this, for example, by performing an associative search of the context field of usage history table 420 to look for one or more apps that are correlated to the current context.

In some embodiments, usage pattern analyzer 410 can determine the context from various sets of variables. For example, usage pattern analyzer 410 can evaluate the context based on global application execution characteristics. These global application characteristics include, for example, the most commonly used application (EMAIL or a social media application or a web browser) and its probability of selection, based on a sorted list of applications the time spent or number of initializations, and the times of execution of different applications.

Alternatively, the context can be based on single application level characteristics, such as the most commonly pressed button in an application, and the probabilities of the various options of buttons that can be pressed or actions that can be made or selected within the application.

The context can also be established based on a multi-application execution characteristic. In other words, the execution of one application may establish a likelihood of launching another application. These factors include the probabilities of execution of a different application once another specified application has been executed, i.e. conditional probabilities of execution, and the length of time the user waits or takes before the next application is expired.

Usage pattern analyzer 410 continues to track such context-based metrics and maintains and refines this information in usage history table 420 over time. It can also transmit this information to a central entity such as remote server 130 for collection and analysis over much larger set of users.

Usage pattern analyzer 410 leverages execution context information in a variety of ways by directing the operating system to take a variety of speculative actions. For example, the execution context can be used to choose particular applications to pro-actively load and place the application code in RAM. Certain applications can be loaded into RAM based on historic execution information before the user actually provides an input to launch the application. For example, a social media application can be loaded into memory at noon every day because the user frequently loads the social media application at her lunch hour. Thus the pre-loading can reduce the latency perceived by the user. Usage pattern analyzer 410 can also direct the mobile operating system to allocate shared resources such as memory to various applications based on their usage histories.

Another action includes speculative instruction stream warm-ups, e.g. loading relevant handler code into memory and executing the handler code up to until a certain point. This action may require the developer to specify a programming model to support the partial execution. Speculative instruction stream warm-ups reduce latency. Usage pattern analyzer 410 could base the decision to warm up based on a context established by other user inputs such as scroll downs, scroll ups, side swipes etc. For example, the first action taken by the user in a social media application is typically a scroll down.

Since the number of instruction streams that can possibly be executed are limited (e.g. when inside a mobile app), probabilistic execution/loading/warm-up can be performed over multiple choices. Essentially the run-time system performs run-ahead execution expecting a user input in the future (decided based on past history) and this can be performed over multiple instruction streams. For example, the two or three most likely instruction streams can be speculatively executed. Conditional probabilities of execution can be used to manage memory e.g. load a different application to memory after a certain application is executed because the user did so as shown by historic data. It is also possible to use usage histories to load balance the system when multiple applications are executing. One example of this factor is to give more priority to the application the user executes more often based on historic data.

Another action is the pre-loading of data based on execution context. For example, the execution context may indicate that a user will launch a web browser and check a favorite news site at a certain time of the day. In this example the speculative action would include loading data indicating the URL of the website and directing the web browser to go to the website in addition to loading the program.

Yet another action is the allocation of memory space based on context. For example when available free space drops below a limit, the context-based execution controller can provide the user usage information to help make decisions on which applications to remove.

Note that while the context-based execution controller is particularly useful in mobile systems because the execution choices are relatively limited, it can also be used in desktop systems. For example on a regular work day, the diversity of the applications and their usage patterns may still be predictable, and most of the applications such as email clients, tele-conference applications, and the like are routinely used. In these desktop systems, the history of program usage is particularly useful context information to allow the context-based execution controller to make predictions about the time to execute a program proactively.

In these systems in addition to history data, other relevant context information can be used to take proactive actions. For example certain EMAIL programs include an integrated calendar application, and the calendar application includes context-based hints about programs that are likely to be used. For example, a scheduled appointment in the electronic calendar requires the use of a virtual meeting program, and this program can be speculatively launched as the meeting time approaches.

Another action in the desktop system environment is speculative boot-up of the workstation based on the location of the user. For example the system can determine the user's location from a GPS receiver, a cellular network, a radio frequency identification (RFID) signal, or a near-field communication signal from a mobile communication device carried by the user. This action allows the user's workstation to be ready when he or she arrives at his or her desk, but requires the communication peripheral to remain active.

Note that in case of a misprediction, the context-based execution controller terminates the speculatively executed application and adjusts the history table to improve the rate of successful predictions. This self-learning mechanism ensures that the changes in user behavior are taken into account to continuously improve the success of the prediction mechanism.

In another embodiment, in addition to automatic learning of application execution context, the user can pre-specify future application execution behavior. In yet another embodiment, software vendors can characterize user behavior and pre-bias the usage pattern analyzer based on the characterization. The characterization may consists of data that indicates which applications are suitable for prediction and which are not. For example an EMAIL application is a good candidate whereas a screen-saver or game is not. This information can be provided by the application vendor and used by the usage pattern analyzer to make predictions. The operating system may support this feature by defining a protocol for applications to request this behavior and the operating system to grant it. The protocol may specify software application program interfaces (APIs), libraries, and other interface protocols to allow the application to request this behavior, specify what portions will be pre-executed, specify pre-execution end points, specify how authentication is handled, etc.

In one particular example of the operation of the context-based execution controller, a user is travelling. The user has taken this trip before and takes a mobile device with her. However the user's route takes her through areas that have no wireless service. In this example, the user's mobile device detects that the travel is beginning, predicts the destination, and can therefore predict the gap in wireless service.

The usage pattern analyzer can detect this condition based on the purchase of a train ticket, GPS location information, WiFi or cellular properties such as changing signal strength, historical travel data such as a history of weekly visits, or other similar means. Moreover multiple methods can be used and cross-correlated to form a stronger inference. Based on this detected travel pattern, the user's mobile device can deduce the destination and prefetch relevant information for the user while still within the wireless service area. Relevant pre-fetch data can include, for example, web pages of interest to the user, news and information about the route of travel, origin, destination, maps, chapters of books that the user is reading or friends have recommended, topical news of interest, tourist information, and so on. The mobile device may also collect personal information of the user's recent history such as photos from a prior social engagement or a movie that the user has marked for watching. The mobile device can remind the user of gifts associated with the people at the location based on previous purchase histories and suggest for a store located near the route of travel.

This information can be cached on the user's mobile device and presented through conventional means (e.g., as cached web pages or notifications) while outside any wireless service area or prior to entering a roaming area with increased access charges. Access to this information could be altered for security or commercial purposes based on location.

Some of the functions of context-based execution controller 400 may be implemented with various combinations of hardware and software. For example, usage pattern analyzer 410 may be implemented as a component of the mobile operating system, as an application program, or in hardware. If implemented in software, some or all of the software components may be stored in a non-transitory computer readable storage medium for execution by at least one processor. In various embodiments, the non-transitory computer readable storage medium includes a magnetic or optical disk storage device, solid-state storage devices such as FLASH memory, or other non-volatile memory device or devices. The computer readable instructions stored on the non-transitory computer readable storage medium may be in source code, assembly language code, object code, or other instruction format that is interpreted and/or executable by one or more processors.

The circuits of FIGS. 3 and 4 or portions thereof may be described or represented by a computer accessible data structure in the form of a database or other data structure which can be read by a program and used, directly or indirectly, to fabricate integrated circuits with the circuits of FIGS. 3 and 4. For example, this data structure may be a behavioral-level description or register-transfer level (RTL) description of the hardware functionality in a high level design language (HDL) such as Verilog or VHDL. The description may be read by a synthesis tool which may synthesize the description to produce a netlist comprising a list of gates from a synthesis library. The netlist comprises a set of gates that also represent the functionality of the hardware comprising integrated circuits with the circuits of FIGS. 3 and 4. The netlist may then be placed and routed to produce a data set describing geometric shapes to be applied to masks. The masks may then be used in various semiconductor fabrication steps to produce integrated circuits of FIGS. 3 and 4. Alternatively, the database on the computer accessible storage medium may be the netlist (with or without the synthesis library) or the data set, as desired, or Graphic Data System (GDS) II data.

While particular embodiments have been described, various modifications to these embodiments will be apparent to those skilled in the art. For example, the context-based execution controller can use various inputs to define the execution context, including but not limited to real time, geographic location, the launching of related mobile apps, etc. In addition, the prediction can use fixed logic criteria or fuzzy logic. Moreover while the embodiments have described taking certain actions such as speculative loading of a program, speculative loading of data, allocation of memory space, many other speculative actions may be taken as well.

Accordingly, it is intended by the appended claims to cover all modifications of the disclosed embodiments that fall within the scope of the disclosed embodiments.

1. A data processing system comprising:
a memory for storing an operating system and a plurality of software applications;
a central processing unit coupled to said memory for executing a selected software application of said plurality of software applications as directed by said operating system;
at least one peripheral device including a real-time clock for defining execution contexts for said plurality of software applications, wherein said execution contexts include a set of one or more environmental factors that include: a time of day, week, location, proximity to other mobile users, and recent selection of other mobile applications; and
a context-based execution controller coupled to said memory and to said at least one peripheral device for taking at least one speculative action with respect to launching said selected software application in response to an execution context indicated by said at least one peripheral device.

2. The data processing system of claim 1, wherein said context-based execution controller comprises:
a usage pattern analyzer coupled to said memory and to said at least one peripheral device and adapted to store history information associated with said execution context for each of said plurality of software applications in said memory, and to use said history information to direct said operating system to take said at least one speculative action.

3. The data processing system of claim 1, wherein said memory comprises:
a volatile memory; and
a non-volatile memory having a first area for storing said operating system and a second area for storing said plurality of software applications.

4. The data processing system of claim 3, wherein said at least one speculative action comprises:
pre-loading data corresponding to said execution context from said non-volatile memory into said volatile memory.

5. The data processing system of claim 3, wherein said at least one speculative action comprises:
pre-loading said software program from said non-volatile memory into said volatile memory.

6. The data processing system of claim 5, wherein said pre-loading comprises allocating a virtual memory space for said one of said plurality of software applications.

7. The data processing system of claim 5, wherein said at least one action comprises transferring a plurality of instructions of said one of said plurality of software applications from said non-volatile memory to said volatile memory.

8. The data processing system of claim 7, wherein said at least one action further comprises creating an entry in a scheduler in said volatile memory and loading a program counter of said central processing unit with an entry point of said software application.

9. The data processing system of claim 1, wherein said context-based execution controller uses said real-time clock to establish an estimated time for launching said one of said plurality of software applications.

10. The data processing system of claim 1, wherein said at least one peripheral device further comprises a global positioning system receiver.

11. A context-based execution controller for managing an application program execution environment for a mobile communication device or the like, comprising:
a usage pattern analyzer; and
a usage history table,
wherein said usage pattern analyzer is coupled to said usage history table and is responsive to a plurality of inputs including a real time signal and an application launch signal to form an execution context for each of a plurality of software applications based on said real time signal and said application launch signal, wherein said execution context includes a set of one or more environmental factors that include: a time of day, week, location, proximity to other mobile users, and recent selection of other mobile applications, and stores said execution context in said usage history table, said usage pattern analyzer further using said real time signal to output an action request with respect to one of said plurality of software applications that is inactive.

12. The context-based execution controller of claim 11 wherein said usage pattern analyzer further forms said history information based on a location signal.

13. The context-based execution controller of claim 11 wherein said usage pattern analyzer further forms said history information based on user inputs.

14. The context-based execution controller of claim 11 wherein said usage pattern analyzer is a component of a mobile operating system.

15. The context-based execution controller of claim 11 wherein said usage pattern analyzer is resident on a remote server and said plurality of applications are associated with the mobile communication device, and said remote server is adapted to be coupled to the mobile communication device over a network.

16. A method comprising:
receiving at least one execution context signal;
receiving an application launch signal;
forming history information based on a plurality of inputs including said at least one execution context signal and said application launch signal;
storing said history information in a usage history table;
accessing said usage history table in response to said at least one execution context signal;
providing an action request associated with a software application based on said usage history table,
said receiving at least one execution context signal comprises receiving a real time signal and a location signal; and
said forming said history information comprises forming said history information based on said real time signal and said location signal.

17. (canceled)

18. The method of claim 16 wherein:
said method further comprises receiving user inputs; and
said forming said history information comprises forming said history information further based on said user inputs.

19. The method of claim 16 wherein said storing said history information further comprises:
storing said history information in an entry of said usage history table; and
storing a software application indicator in said entry of said usage history table.

20. The method of claim 19 wherein:
said accessing said usage history table comprises performing an associative search of said history information based on said at least one execution context signal; and
said providing said action request comprises providing said action request with respect to said software application associated with said software application indicator.
